(19) United States
(12) Patent Application Publication
(10) Pub. No.: US 2017/0330916 A1
(43) Pub. Date: Nov. 16, 2017

(54) COMPLEMENTARY RESISTIVE SWITCHING MEMORY DEVICE HAVING THREE-DIMENSIONAL CROSSBAR-POINT VERTICAL MULTI-LAYER STRUCTURE

(71) Applicant: Industry-University Cooperation Foundation Hanyang University, Seoul (KR)

(72) Inventors: Jinpyo HONG, Seoul (KR); Aram LEE, Gyeongsangnam-do (KR); Yooncheol BAE, Gyeongsangnam-do (KR); Gwangho BAEK, Incheon (KR)

(73) Assignee: Industry-University Cooperation Foundation Hanyang University, Seoul (KR)

(21) Appl. No.: 15/521,961

(22) PCT Filed: Oct. 12, 2015
(86) PCT No.: PCT/KR2015/010719

§ 371 Date: Apr. 26, 2017

(30) Foreign Application Priority Data
Oct. 27, 2014 (KR) 10-2014-0145928

(51) Int. Cl. H01L 27/24; H01L 45/00

(52) U.S. Cl. CPC H01L 27/2481; H01L 45/146; H01L 45/08; H01L 45/1233; H01L 45/1253

(57) ABSTRACT

A complementary resistive switching (CRS) memory device having a three-dimensional crossbar-point vertical multi-layer structure is provided. The CRS memory device having a three-dimensional structure comprises: a conductive pillar; a plurality of CRS memory unit devices surrounding an outer circumferential surface of the conductive pillar and positioned to be spaced apart from each other; and a plurality of word electrode lines making contact with outer circumferential surfaces of the CRS memory unit devices and positioned so as to intersect the conductive pillar, wherein the CRS memory unit devices comprise: a first oxide semiconductor film surrounding the outer circumferential surface of the conductive pillar; a conductive film surrounding the first oxide semiconductor film; and a second oxide semiconductor film surrounding the conductive film. Therefore, a CRS memory device having a CRS-based three-dimensional crossbar-point vertical structure can be provided wherein a CRS device having a three-layer structure is applied as a unit device so as to enable efficient writing and reading without a selection device.

### TECHNICAL FIELD

The present invention relates to a resistive random access memory (ReRAM), and more particularly, to a complementary resistive switching (CRS) memory device having a three-dimensional (3D) crossbar-point vertical multi-layer (ML) structure which does not require a selection device.

### BACKGROUND ART

Recently, research on existing devices based on electric charge control is known to have reached its limit due to the development of the digital information communication and home appliance industries. In order to overcome the limitation, research on new memory devices using a phase change and a magnetic field change is underway. In a method of storing information on a new memory device which is being research, a principle of changing a resistance of a material itself by inducing a change of a state of the material is used.

In a flash memory, which is a representative device of a non-volatile memory, a high operation voltage is required for programing and erasing operations of data. Therefore, when scaling down the flash memory to have a line width of 45 nm or less, a fault may occur due to interference between adjacent cells, and there is a problem such as a slow operation speed and excessive power consumption.

A magnetic random access memory (MRAM), which is another type of non-volatile memory, has some problems on being commercialized due to a complicated manufacturing process, a multi-layer (ML) structure, and a small margin of read and write operations. Therefore, development of a next-generation non-volatile memory device that can replace these devices is an essential research area.

A resistive random access memory (ReRAM) has a structure in which upper and lower electrodes are disposed on a thin film and a resistance variable layer made of an oxide thin film material is interposed between the upper and lower electrodes. Memory operations are implemented by using a phenomenon in which a resistance state of the resistance variable layer is changed according to a voltage applied to the resistance variable layer.

When such a ReRAM is developed to have a three-dimensional (3D) crossbar-point vertical structure, a leakage current is naturally generated. Various selection devices are necessarily required to control the leakage current. For example, in Korean Laid-open Patent Publication No. 10-2013-0137509 (published on Dec. 17, 2013), a ReRAM including a selection device is disclosed.

However, development of a structure and a material that can be used as a selection device in a 3D crossbar-point structure is still being delayed, and there are difficulties in implementing such a selection device.

These difficulties have ultimately resulted in a limitation on the application of a vertical structure, which uses a 3D ML structure, to a ReRAM.

### DISCLOSURE

### Technical Problem

The present invention is directed to providing a resistive random access memory (ReRAM) having a complementary resistive switching (CRS)-based three-dimensional (3D) crossbar-point vertical structure, wherein a CRS device having a three-layer structure is applied as a unit device to enable efficient writing and reading of data even with no selection device.

Further, the present invention is directed to providing a ReRAM having a 3D structure capable of preventing a fault that may occur between adjacent unit resistance layers when such a CRS device is applied as a unit device.

### Technical Solution

One aspect of the present invention provides a complementary resistive switching (CRS) memory device having a three-dimensional (3D) structure. The CRS memory device having a 3D structure includes a conductive pillar, a plurality of unit CRS memory devices configured to surround an outer circumferential surface of the conductive pillar and positioned to be spaced apart from each other, and a plurality of word electrode lines configured to come into contact with outer circumferential surfaces of the unit CRS memory devices and positioned to intersect the conductive pillar. In this case, the unit CRS memory devices includes a first oxide semiconductor film configured to surround the outer circumferential surface of the conductive pillar, a conductive film configured to surround the first oxide semiconductor film, and a second oxide semiconductor film configured to surround the conductive film.

The present invention may have a crossbar-point vertical structure.

The unit CRS memory devices may have a self-selection characteristic.

The first oxide semiconductor film or the second oxide semiconductor film may include a Ti oxide, a Mg oxide, a Ni oxide, a Zn oxide, a Hf oxide, a Ta oxide, an Al oxide, a W oxide, a Cu oxide, or a Ce oxide.

An adjacent distance between the unit CRS memory devices may be 10 nm or more.

Another aspect of the present invention provides a CRS memory device having a 3D structure. The CRS memory device having a 3D structure includes a substrate, a plurality of conductive pillars vertically disposed on the substrate to be spaced apart from each other, a first unit CRS memory device and a second unit CRS memory device, which surround outer circumferential surfaces of the conductive pillars and are positioned to be spaced apart from each other at upper and lower portions thereof, a first word electrode line configured to come into contact with an outer circumferential surface of the first unit CRS memory device and positioned to intersect the conductive pillar, and a second word electrode line configured to come into contact with an outer circumferential surface of the second unit CRS memory device and positioned to intersect the conductive pillar.

The first unit CRS memory device or the second unit CRS memory device may include a first oxide semiconductor film configured to surround the outer circumferential surface of the conductive pillar, a conductive film configured to surround the first oxide semiconductor film, and a second oxide semiconductor film configured to surround the conductive film.

The first oxide semiconductor film or the second oxide semiconductor film may include a Ti oxide, a Mg oxide, a Ni oxide, a Zn oxide, a Hf oxide, a Ta oxide, an Al oxide, a W oxide, a Cu oxide, or a Ce oxide.

### Advantageous Effects

According to the present invention, a resistive random access memory (ReRAM) having a complementary resistive switching (CRS)-based three-dimensional (3D) crossbar-point vertical structure can be provided, wherein a CRS device having a three-layer structure is applied as a unit device to enable efficient writing and reading of data even with no selection device.

Also, when a CRS device having a three-layer structure is integrally formed at one conductive pillar and the one conductive pillar and a plurality of word lines intersect each other, a plurality of unit devices connected to the conductive pillar can be connected to each other. In this case, a parasitic current can be generated through a conductive film of the CRS device and a fault due to such a parasitic current can occur. Therefore, the plurality of unit devices positioned at the one conductive pillar are separated from each other, and thus a fault that may occur between adjacent unit resistance layers can be prevented.

Effects of the present invention are not limited to the above-described effects and other unmentioned effects may be clearly understood by those skilled in the art from the following descriptions.

### DESCRIPTION OF DRAWINGS

FIG. 1 is a schematic diagram illustrating a structure of a complementary resistive switching (CRS) memory device having a three-dimensional (3D) structure according to one embodiment of the present invention.

FIG. 2 is a schematic diagram illustrating a structure of the CRS memory device taken along line A-A′ of FIG. 1.

FIG. 3 is a diagram for describing a parasitic current problem in a CRS memory device having a 3D structure.

FIG. 4 is a schematic diagram illustrating circuits of a CRS memory device having a 3D structure.

FIG. 5 is a schematic diagram illustrating circuits of the CRS memory device having a 3D structure according to the present invention.

### MODES OF THE INVENTION

Hereinafter, embodiments of the present invention will be described in detail with reference to the accompanying drawings.

While the present invention is susceptible to various modifications and alternative forms, specific embodiments thereof are shown by way of example in the drawings and will herein be described in detail. However, it should be understood that there is no intent to limit the invention to the particular forms disclosed but rather the invention is to cover all modifications, equivalents, and alternatives falling within the spirit and scope of the invention defined by the appended claims.

When an element such as a layer, a region, and a substrate is referred to as being disposed “on” another element, it should be understood that the element may be directly formed on the other element or an intervening element may be interposed therebetween.

It should be understood that, although the terms “first,” “second,” etc. may be used herein to describe various elements, components, areas, layers, and/or regions, these elements, components, areas, layers, and/or regions are not limited by these terms.

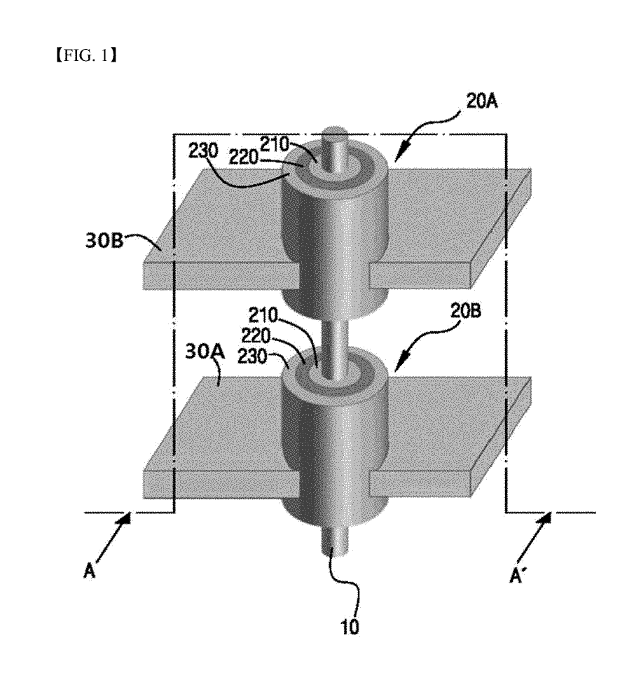

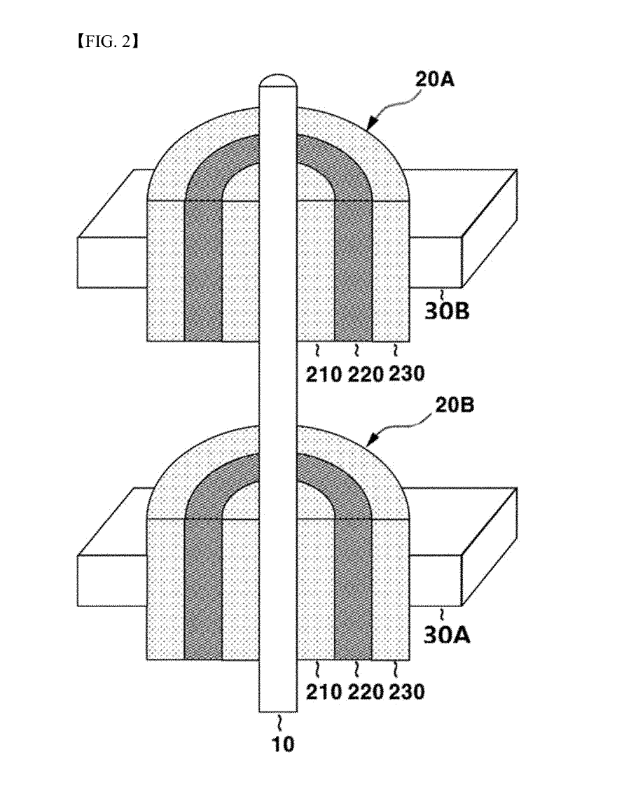

FIG. 1 is a schematic diagram illustrating a structure of a complementary resistive switching (CRS) memory device having a three-dimensional (3D) structure according to one embodiment of the present invention, and FIG. 2 is a schematic diagram illustrating a structure of the CRS memory device taken along line A-A′ of FIG. 1.

Referring to FIGS. 1 and 2, a CRS memory device having a 3D structure according to one embodiment of the present invention may include a conductive pillar 10, a plurality of unit CRS memory devices 20A and 20B, and a plurality of word electrode lines 30A and 30B.

The present invention has a 3D crossbar-point vertical multi-layer (ML) structure, which is a structure in which the conductive pillar 10 and the plurality of word electrode lines 30A and 30B intersect each other and the unit CRS memory devices 20A and 20B are positioned between the conductive pillar 10 and the word electrode lines 30A and 30B.

Also, in this case, the unit CRS memory devices 20A and 20B have a self-selection characteristic. Therefore, no separate selection device is required.

Conventionally, when an additional selection device is essentially used in a 3D crossbar-point vertical structure, since a cross-sectional area of a unit cell occupying the entire 3D vertical structure is increased, a high integration problem may be caused. Accordingly, the present invention uses the unit CRS memory devices in a 3D crossbar-point vertical structure and no separate selection device is required, and thus is advantageous in high integration.

Hereinafter, more specifically, the conductive pillar 10 serves as an electrode of the unit CRS memory device. Also, the conductive pillar 10 may serve as a bit line (BL) electrode.

The conductive pillar 10 may be selected from a group consisting of Pt, Au, Al, Cu, Ti, and an alloy thereof Also, the conductive pillar may include a nitride electrode material or an oxide electrode material. The nitride electrode material includes TiN or WN, and the oxide electrode material includes In₂O₃:Sn(ITO), SnO₂:F(FTO), SrTiO₃, or LaNiO₃.

Meanwhile, although only one conductive pillar is illustrated in FIG. 1, a plurality of pillars may be disposed and spaced apart from each other to form a 3D crossbar-point structure. For example, the plurality of conductive pillars may be disposed in the form of a matrix. For example, the plurality of conductive pillars may be vertically disposed to be spaced apart from each other on a substrate (not illustrated).

The plurality of unit CRS memory devices 20A and 20B may surround outer circumferential surfaces of the conductive pillars 10 and may be positioned to be spaced apart from each other. When the conductive pillars 10 are vertically disposed on the substrate (not illustrated), the plurality of unit CRS memory devices 20A and 20B surround the outer circumferential surfaces of the conductive pillars 10 and are positioned at upper and lower portions thereof to be spaced apart from each other, and the unit CRS memory devices 20A and 20B are separated from each other. Therefore, in this case, the unit CRS memory devices 20A and 20B are in a 3D vertical ML structure.

Meanwhile, when the plurality of conductive pillars 10 are vertically disposed on the substrate (not illustrated) to be spaced apart from each other, the conductive pillars 10 are surrounded by the plurality of unit CRS memory devices 20A and 20B, which are spaced apart from each other.

For example, the first unit CRS memory device 20A and the second unit CRS memory device 20B may be positioned to surround an outer circumferential surface of one conductive pillar 10 and be spaced apart from each other.

In this case, the first unit CRS memory device 20A and the second unit CRS memory device 20B may include a first oxide semiconductor film 210 which surrounds the outer circumferential surface of the conductive pillar 10, a conductive film 220 which surrounds the first oxide semiconductor film 210, and a second oxide semiconductor film 230 which surrounds the conductive film 220.

The first oxide semiconductor film 210 may be positioned to surround the outer circumferential surface of the conductive pillar 10. For example, the first oxide semiconductor film 210 may include a Ti oxide, a Mg oxide, a Ni oxide, a Zn oxide, a Hf oxide, a Ta oxide, an Al oxide, a W oxide, a Cu oxide, or a Ce oxide.

A conductive filament is generated or breaks-down in the first oxide semiconductor film 210 due to a diffusion of oxygen ions by a bias applied to the conductive pillar 10 and the word electrode lines 30A and 30B, and a resistance thereof is changed due to the generation and break-down of the conductive filament.

The conductive film 220 may be positioned to surround the first oxide semiconductor film 210. The conductive film 220 serves as a middle electrode.

Also, the conductive film 220 may include various electrode materials. For example, the conductive film 220 may include Ta, W, Ti, Cu, Ag, TaN, TiN, WN, or Pt.

The second oxide semiconductor film 230 may be positioned to surround the conductive film 220. The second oxide semiconductor film 230 may include a Ti oxide, a Mg oxide, a Ni oxide, a Zn oxide, a Hf oxide, a Ta oxide, an Al oxide, a W oxide, a Cu oxide, or a Ce oxide.

Meanwhile, a material of the second oxide semiconductor film 230 may be the same type as a material of the first oxide semiconductor film 210. Meanwhile, in some cases, a different type of material from the first oxide semiconductor film 210 may be used as the material of the second oxide semiconductor film 230.

A conductive filament is generated or breaks-down in the second oxide semiconductor film 230 due to the diffusion of oxygen ions by the bias applied to the conductive pillar 10 and the word electrode lines 30A and 30B, and the resistance thereof is changed due to the generation and break-down of the conductive filament.

Meanwhile, preferably, an adjacent distance between the unit CRS memory devices 20A and 20B may be 10 nm or more. When the plurality of unit devices positioned at one conductive pillar 10 are integrally connected to each other, the conductive film, which is a component of the CRS device, causes a parasitic current, and a current flows through the conductive film to cause a fault. Therefore, when the unit CRS memory devices 20A and 20B are separated from each other while maintaining the adjacent distance of 10 nm or more between the unit CRS memory devices 20A and 20B, a fault problem caused by the parasitic current which is generated through the conductive film of the CRS device may be effectively prevented.

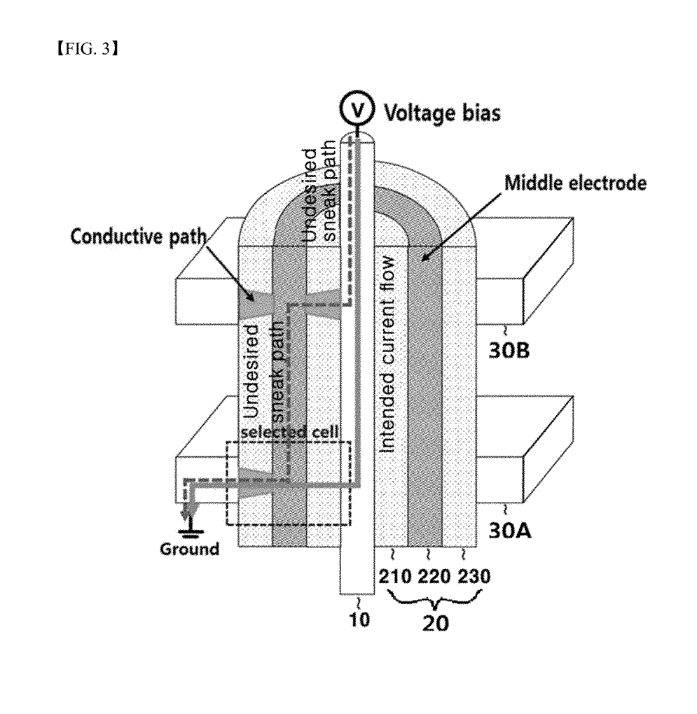

FIG. 3 is a diagram for describing a parasitic current problem in a CRS memory device having a 3D structure.

Referring to FIG. 3, unit CRS memory devices are integrally formed at one conductive pillar 10 to be connected to each other. In this case, the integrally formed unit CRS memory devices 20 may include the first oxide semiconductor film 210 which surrounds the outer circumferential surface of the conductive pillar 10, the conductive film 220 which surrounds the first oxide semiconductor film 210, and the second oxide semiconductor film 230 which surrounds the conductive film 220.

Also, the plurality of word electrode lines 30A and 30B, which come into contact with the outer circumferential surface of the unit CRS memory devices 20 and are positioned to intersect the conductive pillar 10, may be positioned to be spaced apart from each other. In FIG. 3, the unit CRS memory devices have a structure in which the first word electrode line 30A and the second word electrode line 30B are spaced apart from each other at upper and lower portions thereof.

Meanwhile, in this case, portions of the unit CRS memory devices in intersecting regions between the conductive pillar 10 and the word electrode lines 30A and 30B may be defined as unit cells. Therefore, in FIG. 3, a plurality of unit cells which come into contact with one conductive pillar 10 are connected to each other without being separated from each other.

In such a structure of FIG. 3, a current is desired to be driven to flow through an intended current path, which is indicated by a solid arrow, through which the current flows to the first word electrode line 30A through a selected unit cell by applying a voltage bias to the conductive pillar 10. In this case, since the plurality of unit cells are integrally connected to each other, the conductive film, which is a component of the CRS device, causes a parasitic current, and the current flows through an undesired sneak path, which is indicated by a dotted arrow, and causes a fault problem.

Therefore, in the present invention, a problem of the parasitic current which can be generated by the conductive film may be prevented by separating the unit cells from each other.

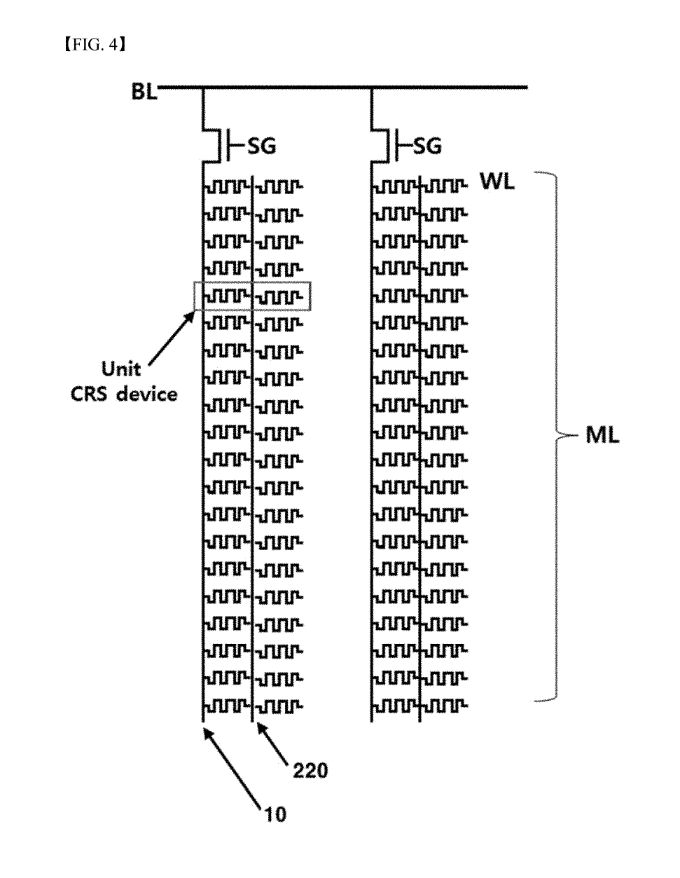

FIG. 4 is a schematic diagram illustrating circuits of a CRS memory device having a 3D structure. A symbol SG illustrated in FIG. 4 refers to a selecting gate.

In FIG. 4, as illustrated in FIG. 3, a plurality of unit cells (unit CRS devices) are integrally connected to one conductive pillar 10 to have a ML structure.

Therefore, in this case, since the conductive film 220 is connected to the plurality of unit cells without being separated therefrom, a parasitic current may be generated through the conductive film 220 and cause a fault.

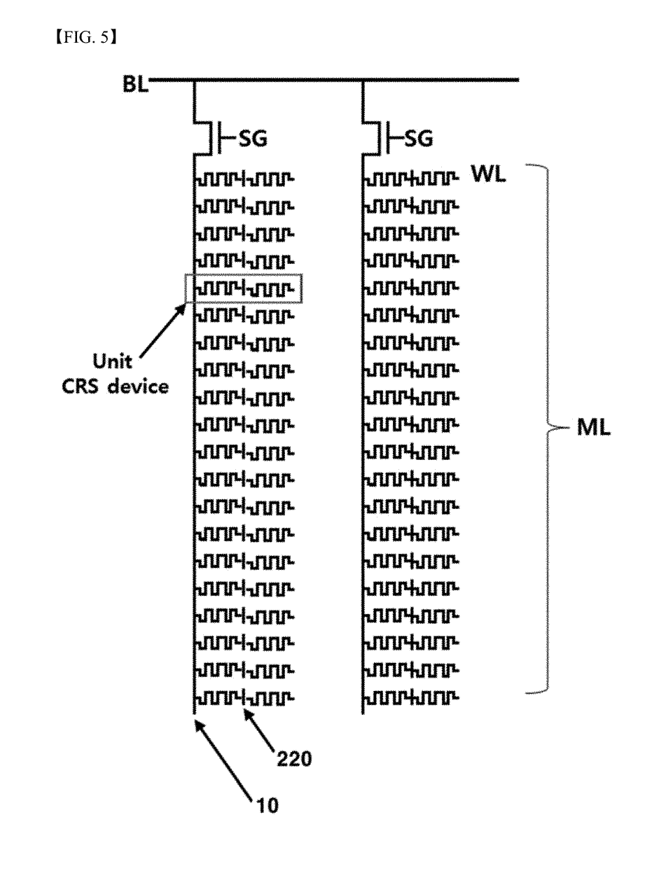

FIG. 5 is a schematic diagram illustrating circuits of the CRS memory device having a 3D structure according to the present invention. The symbol SG illustrated in FIG. 5 refers to a selecting gate.

In FIG. 5, as illustrated in FIG. 1, a plurality of unit CRS devices are positioned at one conductive pillar 10 and are spaced apart from each other to have a ML structure.

Therefore, in this case, since the conductive film 220 is separated from the plurality of CRS devices in unit device units, a fault problem caused by a parasitic current which is generated through the conductive film 220 may be prevented.

According to the present invention, a resistive random access memory (ReRAM) having a CRS-based 3D crossbar-point vertical structure can be provided, wherein a CRS device having a three-layer structure is applied as a unit device to enable efficient writing and reading of data even with no selection device.

Also, when a CRS device having a three-layer structure is integrally formed at one conductive pillar and the one conductive pillar and a plurality of word lines intersect each other, a plurality of unit devices connected to the conductive pillar can be connected to each other. In this case, a parasitic current can be generated through the conductive film of the CRS device and a fault due to such a parasitic current can occur. Therefore, the plurality of unit devices positioned at the one conductive pillar are separated from each other, and thus a fault that may occur between adjacent unit resistance layers can be prevented.

Meanwhile, the embodiments disclosed in this specification and drawings are only examples to facilitate an understanding of the invention, and the invention is not limited thereto. It should be apparent to those skilled in the art that various modifications can be made on the basis of the technological scope of the invention in addition to the embodiments disclosed herein.

1. A complementary resistive switching (CRS) memory device having a three-dimensional (3D) structure, the CRS memory device comprising:
a conductive pillar;
a plurality of unit CRS memory devices configured to surround an outer circumferential surface of the conductive pillar and positioned to be spaced apart from each other; and
a plurality of word electrode lines configured to come into contact with outer circumferential surfaces of the unit CRS memory devices and positioned to intersect the conductive pillar,
wherein the unit CRS memory devices include:
a first oxide semiconductor film configured to surround the outer circumferential surface of the conductive pillar;
a conductive film configured to surround the first oxide semiconductor film; and
a second oxide semiconductor film configured to surround the conductive film.

2. The CRS memory device of claim 1, wherein the CRS memory device has a crossbar-point vertical structure.

3. The CRS memory device of claim 1, wherein the unit CRS memory devices have a self-selection characteristic.

4. The CRS memory device of claim 1, wherein the first oxide semiconductor film or the second oxide semiconductor film includes a Ti oxide, a Mg oxide, a Ni oxide, a Zn oxide, a Hf oxide, a Ta oxide, an Al oxide, a W oxide, a Cu oxide, or a Ce oxide.

5. The CRS memory device of claim 1, wherein an adjacent distance between the unit CRS memory devices is 10 nm or more.

6. A CRS memory device having a 3D structure, the CRS memory device comprising:
a substrate;
a plurality of conductive pillars vertically disposed on the substrate to be spaced apart from each other;
a first unit CRS memory device and a second unit CRS memory device, which surround outer circumferential surfaces of the conductive pillars and are positioned to be spaced apart from each other at upper and lower portions thereof;
a first word electrode line configured to come into contact with an outer circumferential surface of the first unit CRS memory device and positioned to intersect the conductive pillar; and
a second word electrode line configured to come into contact with an outer circumferential surface of the second unit CRS memory device and positioned to intersect the conductive pillar.

7. The CRS memory device of claim 6, wherein the first unit CRS memory device or the second unit CRS memory device includes:
a first oxide semiconductor film configured to surround the outer circumferential surface of the conductive pillar;
a conductive film configured to surround the first oxide semiconductor film; and
a second oxide semiconductor film configured to surround the conductive film.

8. The CRS memory device of claim 7, wherein the first oxide semiconductor film or the second oxide semiconductor film includes a Ti oxide, a Mg oxide, a Ni oxide, a Zn oxide, a Hf oxide, a Ta oxide, an Al oxide, a W oxide, a Cu oxide, or a Ce oxide.
